(19) United States
(12) Patent Application Publication
(10) Pub. No.: US 2016/0065087 A1
(43) Pub. Date: Mar. 3, 2016

(54) CURRENT DETECTING CIRCUIT FOR POWER ELEMENT

(71) Applicant: DENSO CORPORATION, Aichi (JP)

(72) Inventor: Nobusuke NAGAOKA, Kariya-city (JP)

(21) Appl. No.: 14/782,822

(22) PCT Filed: Apr. 7, 2014
(86) PCT No.: PCT/JP2014/001976

§ 371 Date: Oct. 7, 2015

(30) Foreign Application Priority Data
Apr. 9, 2013 (JP) 2013-081225

(51) Int. Cl. H02M 7/537; G01R 19/00

(52) U.S. Cl. CPC H02M 7/537; G01R 19/0092

(57) ABSTRACT

A current detecting circuit includes a current detecting unit and a signal production and transmission unit, and detects a current value through a power element, in response to a pulse width modulation signal inputted from a control circuit. The current detection unit detects the current value through the power element, at the timing when a carrier of the pulse width modulation signal determined based on a signal inputted from the control circuit takes on a minimal value and/or a maximal value. The signal production and transmission unit that produces a detection signal which has a pulse width dependent on the current value detected by the current detection unit, and transmits the detection signal to the control circuit at every cycle of the carrier.

### CROSS REFERENCE TO RELATED APPLICATION

The present disclosure is based on Japanese Patent Application No. 2013-81225 filed on Apr. 9, 2013, the disclosure of which is incorporated herein by reference.

### TECHNICAL FIELD

The present disclosure relates to a current detecting circuit that detects a current value through a power element, according to a PWM (pulse width modulation) signal inputted from a control circuit.

### BACKGROUND ART

For example, assuming that a travel driving motor to be employed in an electric automobile or hybrid electric automobile is controlled by an inverter circuit, a control circuit such as a microcomputer outputs a PWM signal to switching elements, which constitute the inverter circuit, via respective driver ICs. For this kind of configuration, the driver IC is supposedly provided with a feature of detecting a current which flows when the switching element conducts, and transmitting a detection signal to the control circuit.

When a Hall sensor is used to detect a current, a cost increases and a space becomes necessary inside a PCU (power control unit). Therefore, as disclosed in, for example, Patent Literature 1, a shunt resistor is conceivably inserted to a conducting terminal of the switching element in order to detect a current.

### PRIOR ART LITERATURES

### Patent Literature

[PATENT LITERATURE 1] Japanese Patent Application Publication No. 2009-232513.

### SUMMARY OF INVENTION

However, assuming that a driver IC detects a current flowing through a shunt resistor, the current has to be detected when the current is flowing through a power element. Therefore, it is difficult to grasp the detecting timing (herein, what is referred to as a power element is a combination of a switching element and a freewheeling diode connected in parallel with the switching element).

The present disclosure addresses the foregoing situation. An object of the present disclosure is to provide a current detecting circuit for a power element capable of detecting a current value through the power element, synchronously with a carrier cycle for PWM control, and transmitting a detection signal to a control circuit.

According to a current detecting circuit for a power element according to one aspect of the present disclosure, a current detection unit detects a current value through a power element, at the timing when a carrier of a PWM signal determined based on a signal inputted from a control circuit takes on a minimal value and/or maximal value. A signal production and transmission unit produces a detection signal, which has a pulse width dependent on a current value detected by the current detection unit, and transmits the detection signal to the control circuit at each carrier cycle. Therefore, the current detecting circuit can detect the current value at the timing synchronous with the carrier cycle of the PWM signal on the basis of the signal inputted from the control circuit.

When a trigger signal to be outputted at the timing during which the carrier takes on the minimal value and/or maximal value is inputted from the control circuit, the current detection unit may sample a current value. The signal production and transmission unit may append the trigger signal as a header to the detection signal, and transmit the detection signal to the control circuit. In this configuration, the current detection unit can determine the timing of detecting a current using the trigger signal inputted from the control circuit. Since a header is appended to the detection signal sent from the current detecting circuit, the control circuit can obtain the timing when the detection signal should be acquired in order to evaluate the current value.

In the current detection unit, in response to a change in binary levels of the PWM signal, an on-signal output unit may output an on-timing signal at the timing when the power element is turned on, or an off-signal output unit may output an off-timing signal at the timing when the power element is turned off. A current value holding unit samples and holds current values at respective times when the two timing signals of on and off are inputted. An arithmetic unit computes a mean value of the two current values. The signal production and transmission unit may produce a detection signal having a pulse width dependent on the mean value. In this configuration, even when the PWM signal alone is inputted from the control circuit, the current detection unit can obtain the mean value of currents flowing through a power element. Thus, the same current values as the ones obtained at the timings when the carrier takes on the minimal value and/or maximal value can be acquired.

The current detection unit uses a pulse width counter to count a pulse to learn a period when the PWM signal exhibits an on-level of a power element. When the pulse width counter terminates the counting action, an estimation counter may count a value, which is obtained by subtracting a half of a result of the counting from a carrier cycle equivalent value, with the termination time as an origin. When the estimation counter completes the counting, the current flowing through the power element may be detected. In this configuration, due to the counting action of the estimation counter, a current can be detected at the timing when the carrier takes on the subsequent minimal value and/or maximal value.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing the configuration of a motor driving system according to a first embodiment.

FIG. 2 is a functional block diagram of a driver IC.

FIG. 3A is a diagram showing a PWM carrier and phase current; FIG. 3B is a diagram showing a detection timing signal; and FIG. 3C is a diagram showing a waveform of a PWM signal.

FIG. 4 is a functional block diagram showing in detail the configuration of a current detection unit and current transmission unit included in a driver IC.

FIGS. 5A to 5F are timing charts expressing the actions of the current detection unit and current transmission unit.

FIG. 6 is a functional block diagram showing a part with respect to which a microcomputer performs receiving processing of a detection signal.

FIGS. 7A to 7C are timing charts expressing the identical receiving processing.

FIG. 8 is a diagram equivalent to FIG. 4 that shows a second embodiment.

FIGS. 9A to 9F are diagrams equivalent to FIGS. 5A to 5F that shows the second embodiment.

FIG. 10 is a diagram equivalent to FIG. 1 and showing a third embodiment of the present disclosure.

FIG. 11 is a diagram equivalent to FIG. 2 that shows the third embodiment.

FIGS. 12A to 12H are diagrams equivalent to FIGS. 3A to 3C that shows the third embodiment.

FIG. 13 is a diagram equivalent to FIG. 2 that shows a fourth embodiment.

FIGS. 14A to 14H are diagrams equivalent to FIGS. 5A to 5F that show the fourth embodiment.

FIGS. 15A to 15F are diagrams equivalent to FIGS. 5A to 5F and explaining a concrete example of numerical values.

### EMBODIMENTS FOR CARRYING OUT INVENTION

### First Embodiment

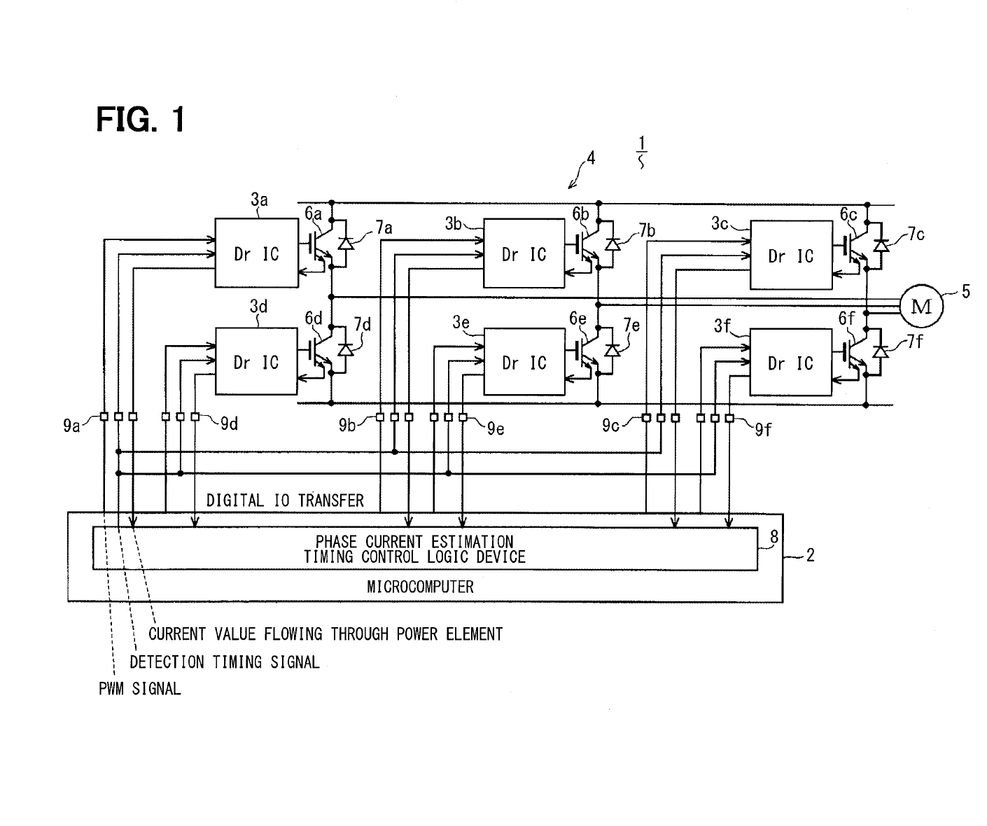

As shown in FIG. 1, a motor driving system 1 includes a microcomputer (i.e., microcomputer) 2, six driver ICs 3 (3a to 3f, i.e., current detecting circuits), an inverter circuit 4, and a motor 5. The inverter circuit 4 is configured by three-phase-bridge connecting switching elements, for example, IGBTs 6 (6a to 6f). Freewheeling diodes 7 (7a to 7f) are connected in reversely parallel with the respective IGBTs 6 (6a to 6f) between the collectors and emitters of the respective IGBTs 6. Namely, the IGBT 6 and freewheeling diode 7 are equivalent to a power element.

The microcomputer 2 includes a phase current estimation timing control logic 8 (hereinafter referred to as a control logic 8) that is a feature to be realized based mainly on software. Transfer of a signal between the microcomputer 2 and each of the driver ICs 3 is performed via a photocoupler 9. In other words, by electrically isolating the microcomputer 2 from the driver ICs, the microcomputer 2 is protected from a high driving voltage (for example, several hundreds of voltages) to be fed to the inverter circuit 4.

The microcomputer 2 outputs a PWM signal to each of the driver ICs 3, and outputs a detection timing signal (i.e., a trigger signal) at the timing when a triangle-wave carrier bottoms out (i.e., takes on a minimal value) (a count value of an up-down counter takes on zero) (see FIG. 3B).

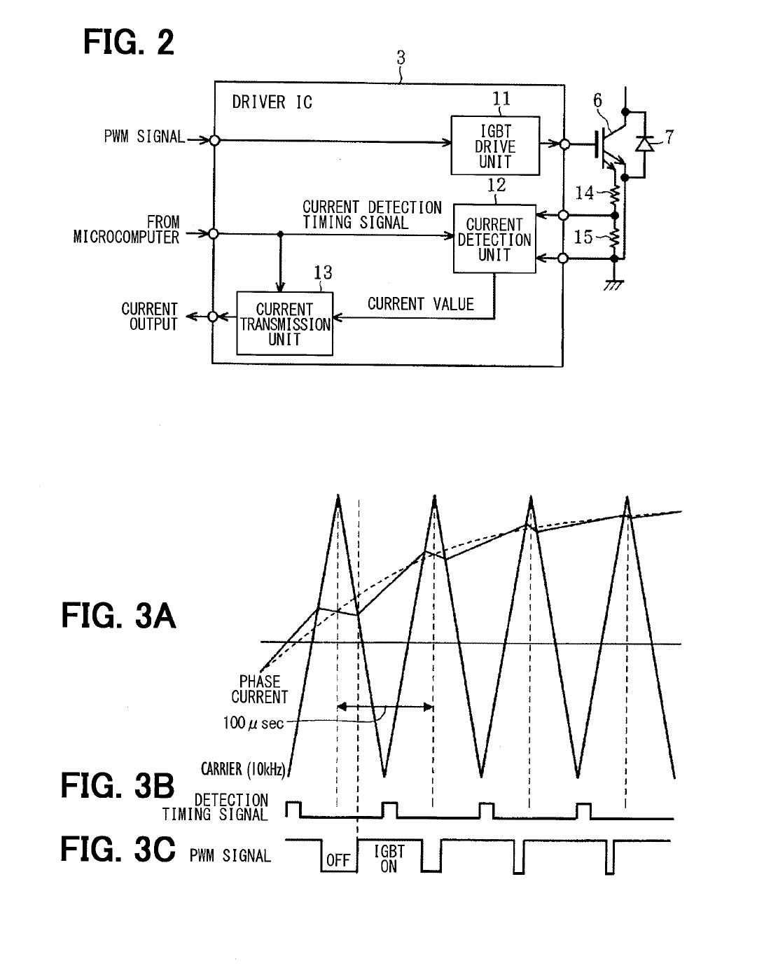

As shown in FIG. 2, the driver IC 3 includes an IGBT drive unit 11, a current detection unit 12, and a current transmission unit 13 (i.e., a signal production and transmission unit). The IGBT drive unit 11 outputs a gate driving signal to a gate of an IGBT (insulated gate bipolar transistor) 6 according to an inputted PWM signal. The IGBT 6 includes a main element 6M and a sense element 6S for current detection. A current dependent on a current flowing into the main element 6M flows into the sense element 6S at a predetermined flow division ratio. Namely, even when a large current flows into the main element 6M, current detection can be readily carried out.

A series circuit including resistive elements 14 and 15 is connected between an emitter and ground of the sense element 6S (in the case of the IGBT included on a lower arm side of the inverter circuit). The current detection unit 12 uses an inputted detection timing signal as a trigger to detect a terminal voltage of the resistive element 15 (i.e., a current detection unit), thus detects a current flowing during a period in which the IGBT 6 is on (see FIGS. 3A and 3B), and then outputs the detected current value to the current transmission unit 13. The detection timing signal is also inputted to the current transmission unit 13. The current transmission unit 13 transmits a current detection signal to the microcomputer 2 via the photocoupler 9.

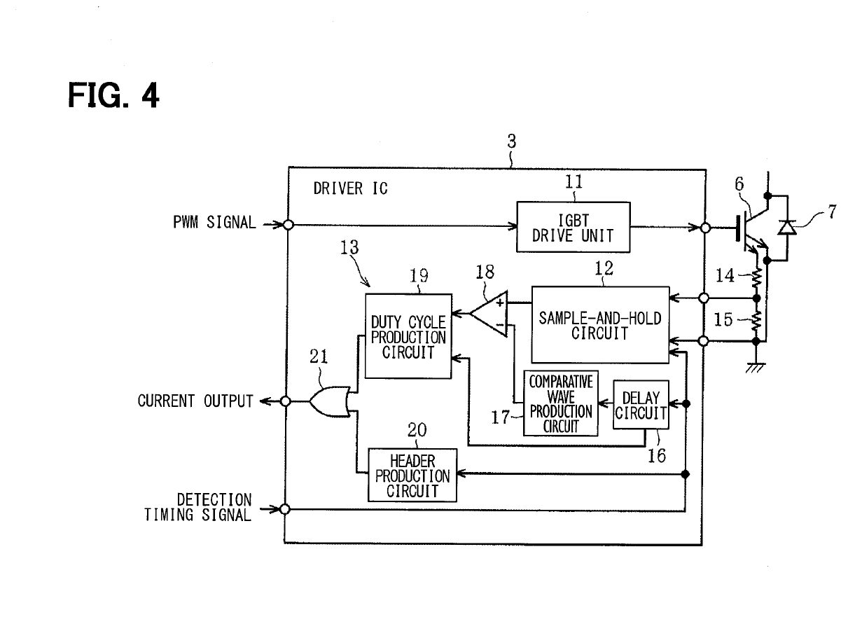

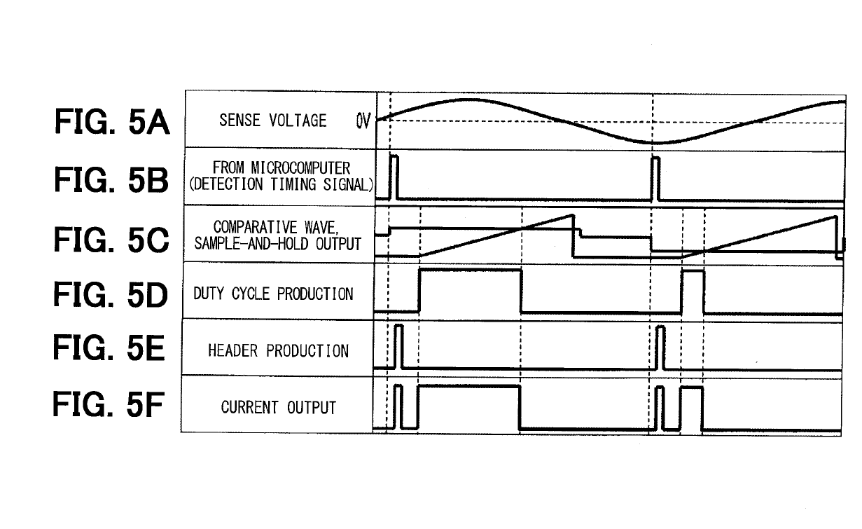

As shown in FIG. 4, the current detection circuit 12 is configured with a sample-and-hold circuit (i.e., a voltage signal production unit), and uses a detection timing signal as a trigger to sample and hold the level of a sense voltage (i.e., a terminal voltage of the resistive element 15) which is inputted at the time point (see FIGS. 5A to 5C).

The current transmission unit 13 includes a delay circuit 16, a comparative wave production circuit 17 (forming a comparative wave production unit together with the delay circuit 16), a comparator 18, a duty cycle production circuit 19, a header production unit 20, and an OR gate 21. The delay circuit 16 appends a predetermined delay time to a detection timing signal, and outputs the detection timing signal to the comparative wave production circuit 17. The comparative wave production circuit 17 uses the detection timing signal, which is inputted via the delay circuit 16, as a trigger to generate a sawtooth wave, which monotonously increases, as a comparative wave (see FIG. 5C).

A comparative wave is applied to an inverting input terminal of the comparator 18, and a sample-and-hold signal (i.e., a voltage signal) of the current detection unit 12 is applied to a non-inverting input terminal of the comparator. An output signal of the comparator 18 and an output signal of the delay circuit 16 are inputted to the duty cycle production circuit 19.

The duty cycle production circuit 19 initializes output of a high-level pulse with a detection timing signal, which is inputted via the delay circuit 16, as a trigger. An output signal of the comparator 18 changes from a high level to a low level when (a comparative wave) becomes larger than (a sample-and-hold signal). Therefore, the duty cycle production circuit 19 ceases output of the high-level pulse with the change of the levels as a trigger (see FIG. 5D). As a result, an output signal of the duty cycle production circuit 19 becomes a duty cycle signal having a high-level pulse width dependent on the level of the sample-and-hold signal.

The header production unit 20 is configured with a multivibrator or the like that uses an inputted detection timing signal as a trigger to generate a one-shot pulse. The one-shot pulse is produced as a header (see FIG. 5E), and is ORed with an output signal (i.e., a duty cycle signal) of the duty cycle production circuit 19 by the OR gate 21. The OR signal is transmitted as a detection signal (i.e., current output) to the microcomputer 2 (see FIG. 5F).

The header production unit 20 works to reshape a waveform for the purpose of transmitting a detection timing signal as a header. The pulse width of the header is not necessarily identical to the pulse width of the detection timing signal, but is set to at least a range of values enabling a predetermined interval to exist between the header and duty cycle signal. In addition, as described later, the pulse width of the header is designated to be narrower than a minimal pulse width of the duty cycle signal. In other words, an aim of applying a delay time using the delay circuit 16 is to create time to enable distinction of the header from the duty cycle signal in the detection signal to be transmitted to the microcomputer 2.

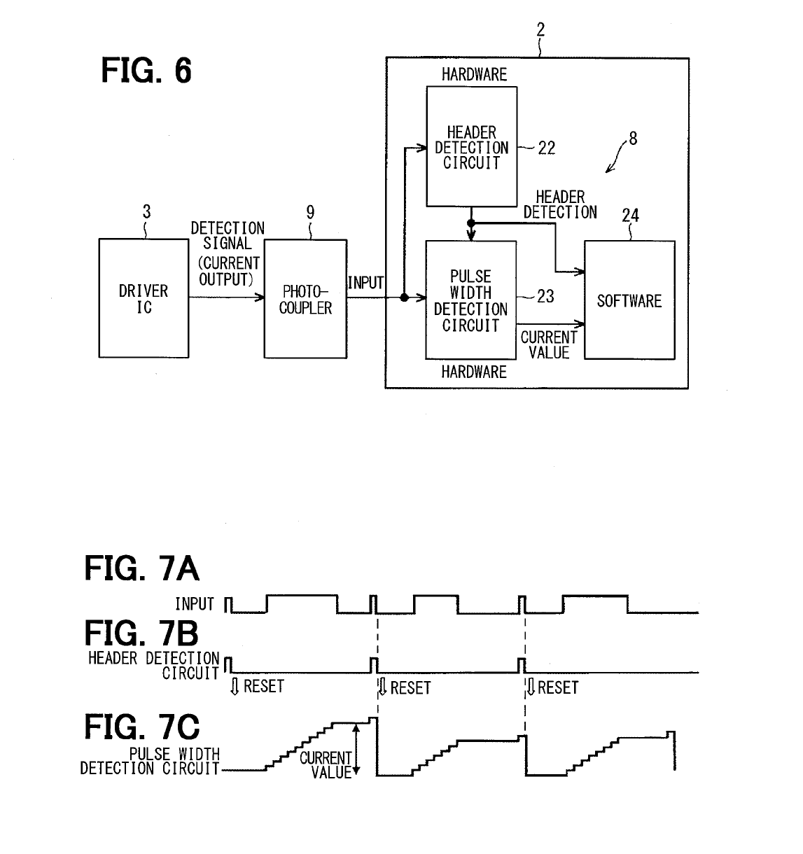

As shown in FIG. 6, when a detection signal outputted from the driver IC 3 is inputted to the microcomputer 2 via the photocoupler 9, the detection signal is inputted to a header detection circuit 22 and pulse width detection circuit 23 of the control logic 8. When the header detection circuit 22 detects a header contained in the detection signal on the basis of, for example, the fact that the pulse width of the header falls below a threshold defined with a minimal pulse width of a duty cycle signal, the header detection circuit 22 outputs the header detection signal to the pulse width detection circuit 23 and software 24 (a feature to be implemented by software). The software 24 recognizes the header detection signal through, for example, interrupting or polling.

The pulse width detection circuit 23 is formed with a counter that performs counting during a period during which a detection signal exhibits a high level. When a header detection signal is inputted to the pulse width detection circuit, the pulse width detection circuit 23 is reset (see FIGS. 7B and 7C). The count value of the pulse width detection circuit 23 is equivalent to a detection current value, and the software 24 acquires the count value with the header detection signal as a trigger. Since the count value includes a value representing the number of counted header pulses, the software 24 obtains the current value by subtracting the value, which represents the number of counted header pulses, from the obtained count value.

As mentioned above, according to the present embodiment, the current detection unit 12 of the driver IC 3 detects a current, which flows when the IGBT 6 conducts, at the timing equivalent to the timing when a carrier of a PWM signal determined based on a signal inputted from the microcomputer 2 takes on a minimal value. The current transmission unit 13 produces a detection signal having a pulse width dependent on the current value detected by the current detection unit 12, and then transmits the detection signal to the microcomputer 2 at every carrier cycle. Therefore, the driver IC 3 can detect a current at the timing synchronous with the carrier cycle of the PWM signal on the basis of the signal inputted from the microcomputer 2.

The current detection unit 12 samples a current value when a detection timing signal is inputted from the microcomputer 2. The current transmission unit 13 appends a trigger signal as a header to a detection signal, and then transmits the detection signal to the microcomputer 2. Therefore, the current detection unit 12 can determine the timing of current detection using the detection timing signal. Since the header is appended to the detection signal sent from the driver IC 3, the microcomputer 2 can obtain the timing when the detection signal should be acquired in order to evaluate the current value.

Further, the current detection unit 12 outputs a sample-and-hold signal dependent on a current value. When the current transmission unit 13 inputs a detection timing signal, the delay circuit 16 appends a predetermined delay time. Thereafter, the comparative wave production circuit 17 initiates production of a comparative wave that is a sawtooth wave. The comparator 18 compares the level of the sample-and-hold signal with the level of the comparative wave, whereby a detection signal having a pulse width dependent on the voltage level of the sample-and-hold signal is produced.

Therefore, a detection signal can be produced as a signal exhibiting a duty cycle dependent on a current value. Compared with a case where a voltage signal dependent on the current value is transmitted, the noise immunity of the detection signal can be upgraded. Since a delay time is appended, the microcomputer 2 that receives the detection signal can readily distinguish a header from a duty cycle signal representing a current value. A detection timing signal may be outputted at the timing when a carrier takes on a maximal value (i.e., peak), or may be outputted at the timing when the carrier takes on each of a minimal value and the maximal value.

### Second Embodiment

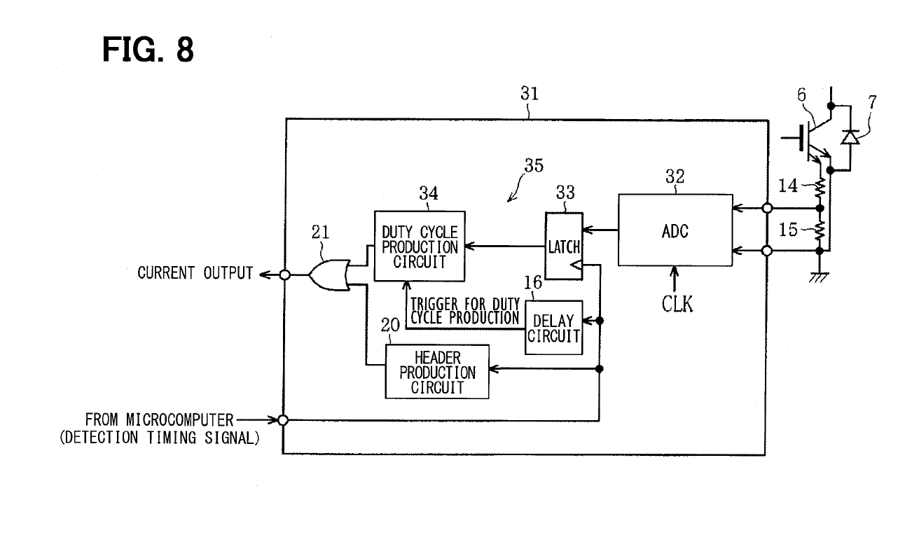

As shown in FIG. 8, a driver IC 31 (i.e., current detecting circuit) of a second embodiment excludes the sample-and-hold circuit 12, a comparative wave production circuit 17, a comparator 18, and a duty cycle production circuit 19, and includes an analog-to-digital converter 32 (i.e., a current detection unit), latch 33 (i.e., a latch circuit), and a duty cycle production circuit 34 (i.e., a pulse signal production unit) in place of the excluded circuits. It is noted that the IGBT drive unit 11 is not shown in FIG. 8. The components other than the analog-to-digital converter 32 constitute a current transmission unit 35 (i.e., a signal production and transmission unit).

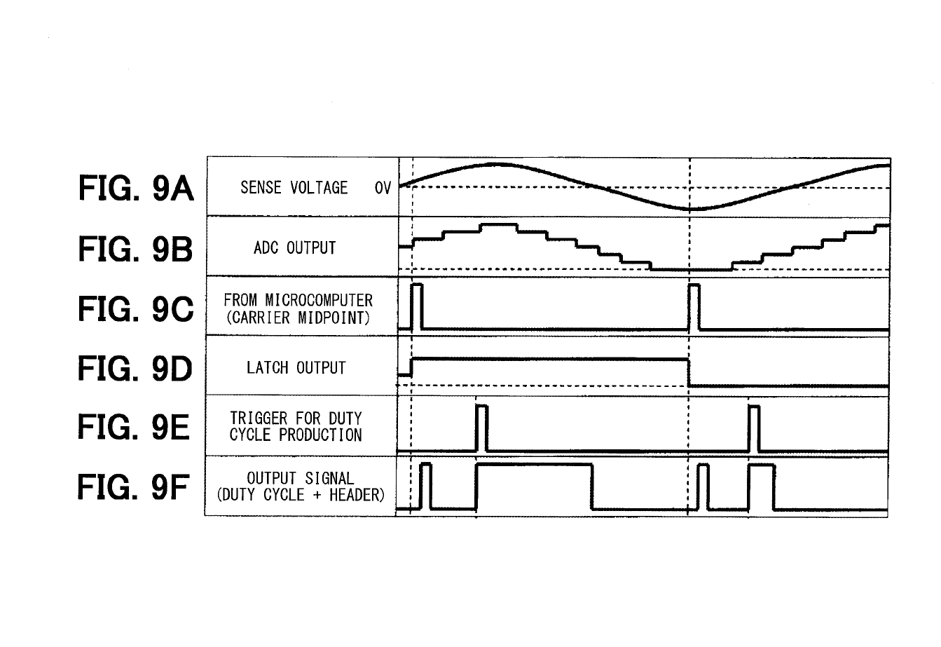

The analog-to-digital converter 32 performs analog-to-digital conversion of a sense voltage every time a pulse of a clock signal CLK is inputted (see FIGS. 9A and 9B). The latch 33 latches data, which results from analog-to-digital conversion performed by the analog-to-digital converter 32, with a detection timing signal as a trigger (see FIGS. 9C and 9D). The duty cycle production circuit 34 initiates, as in the first embodiment, output of a pulse signal with the detection timing signal, which is applied via the delay circuit 16, as a trigger, and terminates output of the pulse signal when a pulse width represented by a data value applied via the latch 33 is attained (see FIGS. 9E and 9F).

As mentioned above, according to the second embodiment, the driver IC 31 includes the analog-to-digital converter 32, as the current detection unit, that performs analog-to-digital conversion of a sense voltage equivalent to a current value. The current transmission unit 35 includes the latch 33 that latches current value data, which results from analog-to-digital conversion, when a detection timing signal is inputted, and the duty cycle production circuit 34 that produces a detection signal having a pulse width dependent on the current value data. Therefore, detection of a current value and production of the detection signal can be performed by digital circuits.

### Third Embodiment

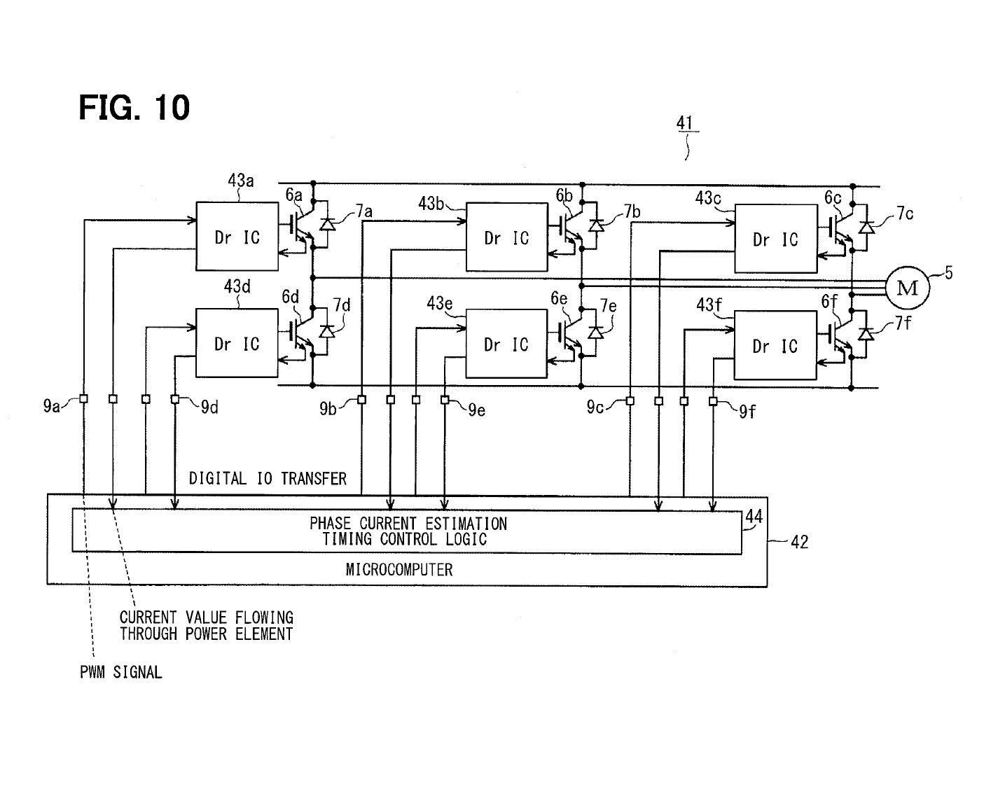

As shown in FIG. 10, a motor driving system 41 according to a third embodiment substitutes a microcomputer 42 (i.e., a control circuit) and driver ICs 43 (i.e., current detecting circuits) for the microcomputer 42 and driver ICs 3. A control logic 44 of the microcomputer 42 does not output a detection timing signal to the driver ICs 43 but outputs a PWM signal alone.

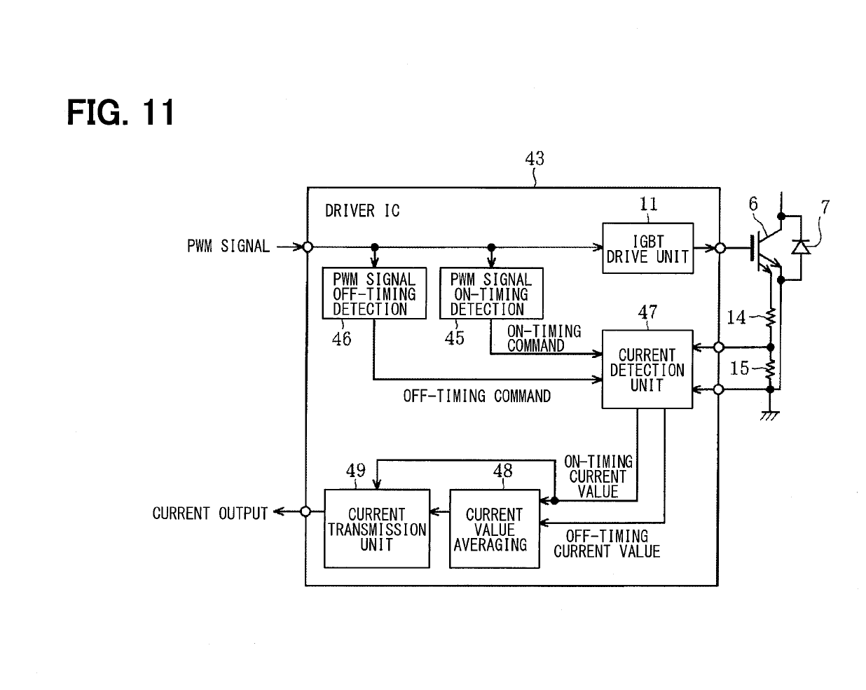

As shown in FIG. 11, the driver IC 43 includes a PWM signal on-timing detection unit 45 (i.e., an on-signal output unit), a PWM signal off-timing detection unit 46 (i.e., an off-signal output unit) (it is noted that on-signal output unit and off-signal output unit constitute a current detection unit), a current detection unit 47 (i.e., a current value holding unit), a current value averaging unit 48 (i.e., an arithmetic unit), and a current transmission unit 49 (i.e., a signal production and transmission unit).

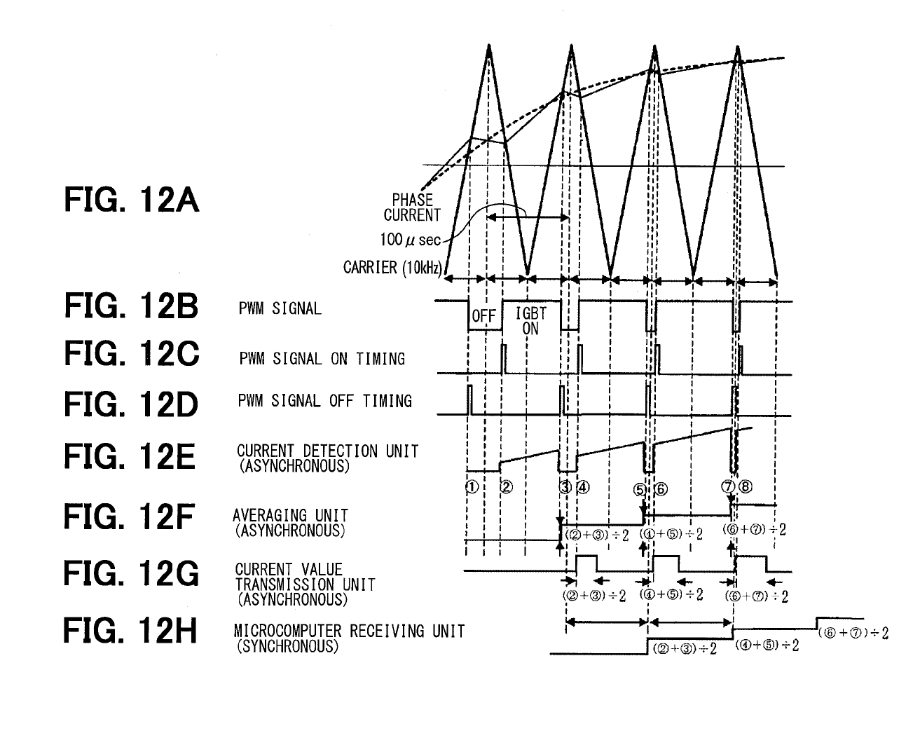

Each of the on-timing detection unit 45 and off-timing detection unit 46 outputs a one-shot pulse synchronously with a leading edge of a PWM signal (i.e., at the timing when the IGBT 6 is turned on) or a trailing edge of the PWM signal (i.e., at the timing when the IGBT 6 is turned off) (see FIGS. 12B to 12D). The one-shot pulse is inputted as an on-timing command (i.e., an on-timing signal) or an off-timing command (i.e., an off-timing signal) to the current detection unit 47.

The current detection unit 47 samples an inputted sense voltage at the timing of inputting an on-timing command or an off-timing command, and the current detection unit 47 then outputs the sampled voltage as an on-timing current value or off-timing current value to the current value averaging unit 48. The current value averaging unit 48 outputs a half of the sum of the on-timing current value and off-timing current value as a mean value to the current transmission unit 49 (see FIG. 12F). If necessary, the current value averaging unit 48 may refer to the on-timing command and off-timing command.

The current transmission unit 49 produces a detection signal having a pulse width dependent on an inputted current mean value, and transmits the detection signal to the microcomputer 2 (see FIG. 12G). The microcomputer 2 then acquires the mean value, which is transmitted from the driver IC 43, during the next cycle of a carrier (see FIG. 12H). In the third embodiment, unlike the first and second embodiments, a header is not appended to a detection signal. In addition, the o pulse width of the detection signal produced by the current transmission unit 49 is designated to be about 50% of the carrier cycle in a case where a current value becomes maximal in a range. This prevents a pulse from exceeding the carrier cycle in a case where the current value is high.

In FIGS. 12A to 12H, timings are indicated with encircled numerals. The timings (2) to (8) are alternating on and off-timings. A mean value is obtained with respect to each of a pair of the timings (2) and (3), a pair of the timings (4) and (5), and a pair of the timings (6) and (7).

A mean value of currents flowing through the IGBT 6 is obtained in the aforesaid embodiments. Alternatively, a mean value of reflux currents (i.e., currents flowing through a power element) flowing via the freewheeling diode 7 may be obtained in the same manner. However, in this case, the detection timings for the current detection unit 47 are a pair of the timings (1) and (2), a pair of the timings (3) and (4), a pair of the timings (5) and (6), and a pair of the timings (7) and (8) (that is, an off-period of the IGBT 6).

A mean value of currents flowing through the IGBT 6 and a mean value of currents flowing through the diode 7 may be independently transmitted to the microcomputer 2 (however, addition of a photocoupler is needed). With the use of the mean values of currents, a resolution in current detection can be upgraded.

As mentioned above, according to the third embodiment, the PWM signal on timing detection unit 45 and PWM signal off timing detection unit 46 output an on-timing command and off-timing command respectively at the timings when the IGBT 6 is turned on and off respectively according to a change of binary levels of a PWM signal. When the two on and off timing comments are inputted, the current detection unit 47 samples and holds current values. The current value averaging unit 48 computes a mean value of the two current values. The current transmission unit 49 produces a detection signal having a pulse width dependent on the mean value. Therefore, since a mean value of currents flowing during a period during which the IGBT 6 is on is obtained, even when a detection timing signal is not, unlike it is in the first and second embodiments, inputted from the microcomputer 2, current detection can be performed similarly.

### Fourth Embodiment

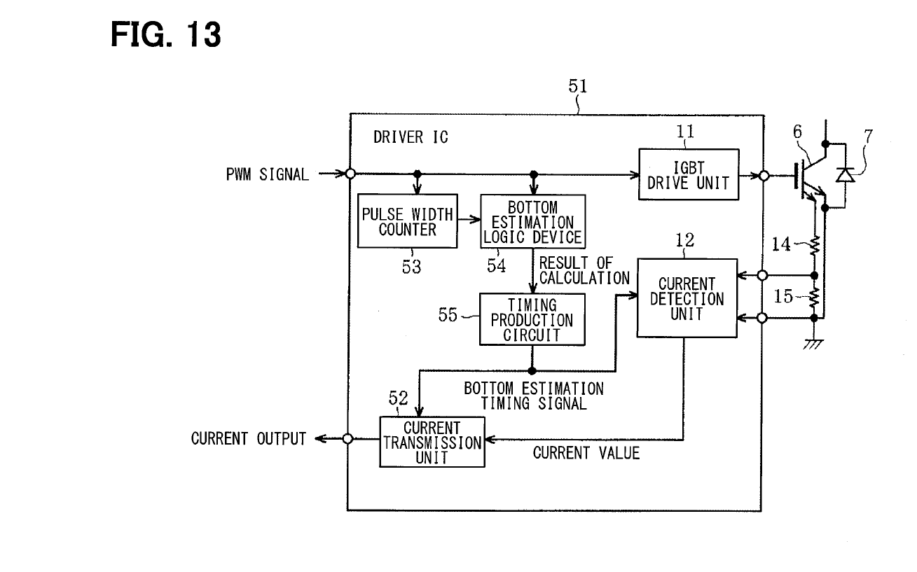

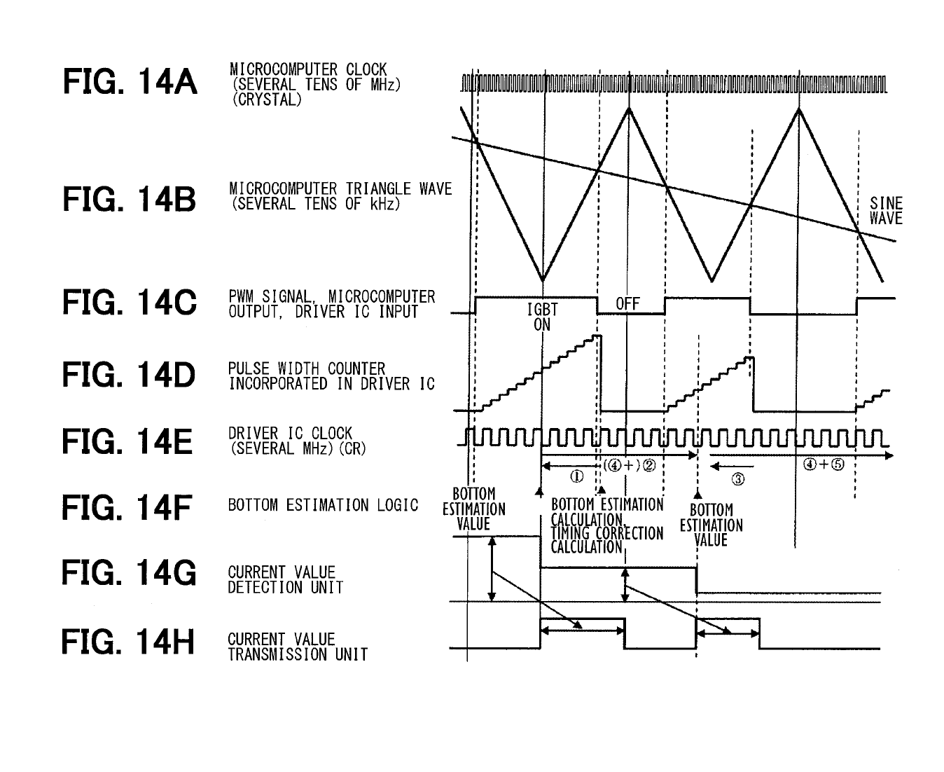

As shown in FIG. 13, a driver IC 51 (i.e., a current detecting circuit) of the fourth embodiment substitutes a current transmission unit 52 (i.e., a signal production and transmission unit) for the current transmission unit 13 of the driver IC 3 of the first embodiment, and additionally includes a pulse width counter 53, a carrier bottom estimation logic unit 54, and a timing production circuit 55 (i.e., an estimation counter). The pulse width counter 53 performs a counting action on the basis of a clock signal of a frequency of several MHz, which is produced by a CR oscillation circuit that is not shown, during a period in which an inputted PWM signal exhibits a high level (see FIGS. 14C to 14E).

As shown in FIG. 14A, a clock signal employed in the microcomputer 2 is a clock signal of a frequency of several tens of MHz that is fed from a high-precision oscillation circuit which uses a crystal oscillator. The frequency of a PWM carrier is, for example, about several tens of kHz (see FIG. 14B). A current of a sine wave is shown through linear approximation.

The carrier bottom estimation logic unit 54 calculates a count value (i.e., a bottom estimation value), which is equivalent to the timing when a carrier takes on a minimal value, on the basis of a count value of the pulse width counter 53, and outputs the count value to the timing production circuit 55. The timing production circuit 55 is a counter that performs a counting action on the basis of a clock signal produced by the CR oscillation circuit. In response to a bottom estimation value sent from the carrier bottom estimation logic unit 54, the timing production circuit 55 loads the estimation value and performs, for example, a counting down action. When the count value becomes zero, a bottom timing estimation signal is outputted to the current detection unit 12 and current transmission unit 52 (see FIG. 14F).

The current detection unit 12 samples and holds a sense voltage with a bottom timing estimation signal as a trigger, and outputs the sense voltage to the current transmission unit 52 (see FIG. 14G). The current transmission unit 52 brings an output signal to a high level with the bottom timing estimation signal as a trigger. Thereafter, the current transmission unit 52 retains the output signal at the high level during a period dependent on the level of a sample-and-hold signal inputted from the current detection unit 12, and thus produces as a detection signal pulses whose duty cycle varies (see FIGS. 14G and 14H).

In an initial state prior to the output of an initial PWM signal, the timing production circuit 55 outputs a bottom timing estimation signal associated with a case where the duty cycle of the PWM signal is equivalent to 50%. In the initial state, a current has not yet been outputted via the inverter circuit 4. Therefore, even if a little error is observed in a minimal detection current value, no problem would arise in terms of control.

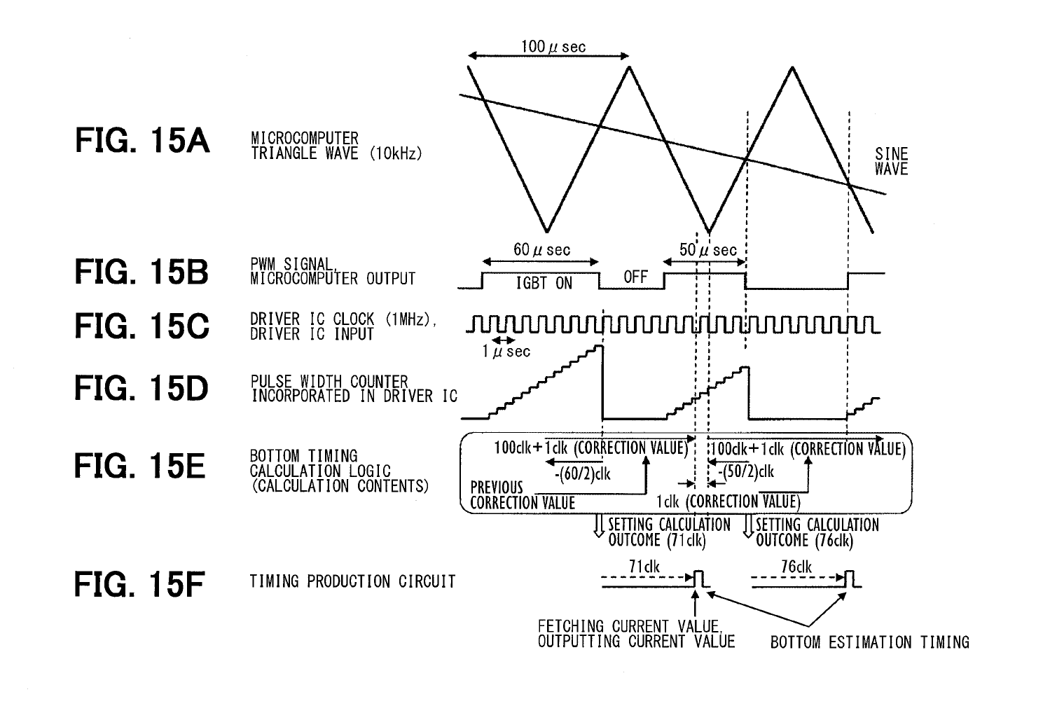

As shown in FIG. 15, it is assumed that a carrier frequency is 10 kHz (cycle of 100 μs), and the frequency of a clock signal of the driver IC 51 is 1 MHz (cycle of 1 μs), and the count value of the pulse width counter 53 is initially “60.” The count value is latched at the trailing edge of the PWM signal. The timing production circuit 55 subtracts “60/2” from “100” that is a carrier cycle equivalent value, and outputs a value of “71,” which is obtained by adding “1” (i.e., predetermined value) as a correction value, as a result of calculation to the timing production circuit 55 (see FIG. 15E). The correction value of “1” is added in order to correct a discrepancy attributable to the fact that the pulse width is obtained by counting pulses of the clock signal having the cycle of 1 μs.

A count value of “71” is loaded to the timing production circuit 55. When the count value is counted down to zero, a bottom timing estimation signal is outputted. A counting action is ceased until the count value is loaded next. Supposing a count value which the pulse width counter 53 obtains during the next carrier cycle is “50,” the timing production circuit 55 subtracts “50/2” from a carrier cycle equivalent value of “100,” and outputs a value of “76,” which is obtained by adding “1” as a correction value, as a result of calculation.

According to the fourth embodiment as mentioned above, the pulse width counter 53 counts pulses to learn a period during which a PWM signal exhibits an on-level signifying that the IGBT 6 is on. As soon as the pulse width counter 53 terminates the counting action, the timing production circuit 55 counts down from a value, which is obtained by subtracting a half of a result of the counting from a carrier cycle equivalent value, with the termination time as an origin. When the timing production circuit 55 completes the counting (counts down to zero), the current detection unit 12 detects a current that flows when the IGBT 6 is turned on.

As mentioned above, by estimating the timing when a carrier exhibits a bottom value, the driver IC 51 can sustain synchronism with processing of the microcomputer, though the driver IC 51 cannot, unlike the one of the first embodiment, obtain a detection timing signal from the microcomputer 2. The timing production circuit 55 counts down from a value obtained by adding 1 to a value obtained by subtracting a half of a result of the counting from a carrier cycle equivalent value, whereby a discrepancy attributable to the fact that a pulse width is obtained by counting pulses of a clock signal of the driver IC 51 can be corrected. The timing when a carrier exhibits a peak value may be estimated in place of the timing when the carrier exhibits a bottom value. Otherwise, the timings when the carrier exhibits the bottom and peak values respectively may be estimated.

### Modification

The present disclosure is not only limited to the embodiments described so far or shown in the drawings, but may also be modified or expanded as described below.

A driver IC with a current detection feature need not be provided for each of IGBTs 6 constituting the inverter circuit 4. For example, if detection of a current is needed for motor control, the driver IC may be provided for each of the IGBTs 6d to 6f on the lower arm side of the inverter circuit. In a case where currents of two phases alone are detected, and a current of the remaining phase is computed by the microcomputer 2, the driver IC may be provided for the two phases.

The present disclosure may be applied to an H bridge circuit, a half-bridge circuit, or a circuit in which one power element is connected in series with a load for the purpose of high-side or low-side driving.

An IGBT without a sense element may be adopted. A switching element is not only limited to the IGBT, but may also be realized with a MOSFET or bipolar transistor.

In the first and second embodiments, a header may be produced by the driver IC 3 and then applied. If processing of the microcomputer 2 and processing of the driver IC 3 are synchronized with each other, the header need not be employed.

In the fourth embodiment, a value to be added as a correction value is not limited to “1.” The value need not be added in a case where correction is unnecessary.

A carrier cycle or the cycle of a clock signal may be properly varied depending on an individual design.

1. A current detecting circuit for a power element that detects a current value through the power element, in response to a PWM (pulse width modulation) signal inputted from a control circuit, the current detecting circuit comprising:
a current detection unit that detects the current value through the power element at a timing when a carrier of the PWM signal determined based on a signal inputted from the control circuit takes on a minimal value and/or a maximal value, and
a signal production and transmission unit that produces a detection signal which has a pulse width dependent on the current value detected by the current detection unit, and transmits the detection signal to the control circuit at every cycle of the carrier.

2. The current detecting circuit for a power element according to claim 1,
wherein, when the current detection unit inputs a trigger signal outputted from the control circuit at the timing when the carrier takes on the minimal value and/or maximal value, the current detection unit samples the current value; and
wherein the signal production and transmission unit appends the trigger signal as a header to the detection signal, and transmits the detection signal to the control circuit.

3. The current detecting circuit for a power element according to claim 2,
wherein the current detection unit includes a voltage signal production unit that produces a voltage signal dependent on a sampled current value;
wherein the signal production and transmission unit includes a comparative wave production unit that, when a trigger signal is inputted, produces a comparative wave that is a wave to start monotonously changing a level of the comparative wave upon elapse of a predetermined delay time; and
wherein the detection signal having a pulse width dependent on a level of the voltage signal is produced by comparing the level of the voltage signal with the level of the comparative wave.

4. The current detecting circuit for a power element according to claim 2,
wherein the current detection unit includes an analog-to-digital converter that performs analog-to-digital conversion of the current value; and
wherein the signal production and transmission unit includes a latch circuit that latches current value data, which results from the analog-to-digital conversion, when the trigger signal is inputted, and a pulse signal production unit that produces a detection signal having a pulse width dependent on the current value data.

5. The current detecting circuit for a power element according to claim 1,
wherein the current detection unit includes:
an on-signal output unit that outputs an on-timing signal at a timing when the power element turns on in response to a change in binary levels of the PWM signal,
an off-signal output unit that outputs an off-timing signal at the timing when the power element turns off in response to the change in binary levels of the PWM signal,
a current value holding unit that samples and holds the current value when each of the on-timing signal and the off-timing signal is inputted, and
an arithmetic unit that computes a mean value of two current values; and
wherein the signal production and transmission unit produces a detection signal which has a pulse width dependent on the mean value.

6. The current detecting circuit for a power element according to claim 1,
wherein the current detection unit includes:
a pulse width counter that performs counting of a pulse to learn a period during which the PWM signal exhibits an on-level of the power element, and
an estimation counter that, when the pulse width counter terminates performing the counting, performs counting of a value, which is obtained by subtracting one half of a result of the counting from a cycle equivalent value of the carrier, at a timing of terminating the counting performed by the pulse width counter as a starting time; and
wherein a current value through the power element is detected when the estimation counter completes the counting.

7. The current detecting circuit for a power element according to claim 6,
wherein the estimation counter counts the value obtained by adding a predetermined value to the value, which is obtained by subtracting one half of the result of the counting from a cycle equivalent value of the carrier.
